(19) United States
(12) Patent Application Publication
(10) Pub. No.: US 2007/0018298 A1
(43) Pub. Date: Jan. 25, 2007

(54) Optimized multi-apparation assembly

(75) Inventor: Patrice Gamand, Douvres La Delivrande (FR)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N.V., Eindhoven (NL)

(21) Appl. No.: 10/562,295

(22) PCT Filed: Jun. 16, 2004
(86) PCT No.: PCT/IB04/02022

§ 371 Date: Dec. 22, 2005

(30) Foreign Application Priority Data
Jun. 20, 2003 (EP) 033000357

(51) Int. Cl. H01L 23/02

(52) U.S. Cl. 257/686

(57) ABSTRACT

The invention relates to a microelectronic chip assembly ASS comprising at least three microelectronic chip ICH, TCH, BCH stacked together and on which integrated devices are formed. At least one of the chip, called intermediate chip ICH, includes via holes VH running through said chip ICH and filled with conductive material is realized from a high-ohmic substrate on which are formed devices for the functioning of at least two other microelectronic chips, called top chip TCH and bottom chip BCH. Said top and bottom chips TCH and BCH are connected by flip chip bonding respectively on top face TF and bottom face BF of said intermediate chip ICH and said via holes VH are electrically connected to pads of said top and bottom chips TCH and BCH.

### FIELD OF THE INVENTION

This invention relates to the field of electronic system packaging. More particularly the invention relates to assembly incorporating at least three microelectronic chips on which integrated devices are formed, said chips being stacked together and at least one of the chips including via holes running through said chip and filled with conductive material. The invention also relates to a microelectronic chip intended to be used in such an assembly and to a packaged system including at least such an assembly. Finally, the invention relates to a method of manufacturing such an assembly.

### BACKGROUND OF THE INVENTION

Such an assembly is known from document US 2001/0006257. In this document a method is described of realizing an assembly of at least three microelectronic chips on which integrated devices are formed, said chips being stacked together and at least one of the chips including via holes running through said chip and filled with conductive material.

In this document chips are stacked one on top of the other by inserting an adhesive layer between each pair of chips. Holes are realized once the chips are superposed run-through the top chip and filled with conductive material. This implies that said holes are realized in a dedicated part of the chip in order not to destroy the devices integrated on the chips. The assembly proposed in this document is an assembly of similar active chips. Once the three chips are superposed and connected, the connection to external circuits or to passive elements has to be realized through a protective layer coated on the highest chip.

The assembly proposed in this prior art document therefore presents drawbacks and limitation regarding the quality of the miniaturization and the implementation of such an assembly for complex systems.

### SUMMARY OF THE INVENTION

It is an object of the present invention to describe a miniaturized and an easy-to-implement assembly of several microelectronic chips, suitable for complex systems.

This is achieved with a microelectronic chip assembly as presented in the introductory paragraph and such that said chip including via holes, called intermediate chip, is realized from a high-ohmic substrate on which devices are arranged to be used by at least two other microelectronic chips, called top and bottom chips, connected by flip chip bonding on top and bottom faces of said intermediate chip, respectively, said via holes realizing an electrical connection between pads of said top and bottom chips. By high-ohmic,

This assembly makes it possible to prepare the intermediate chip first and independently of the assembly steps. Consequently, via holes are realized during manufacture of said intermediate chip between the integrated devices and no specific surface needs to be dedicated to them on said intermediate chip. A very good miniaturization is therefore obtained.

The intermediate chip is manufactured from a high-ohmic substrate on which specific devices to be used by the two other microelectronic chips are arranged. By high-ohmic, a semiconductor material is meant whose part of which has a resistivity of more than 100 ohm.cm and preferably of at least 1 kohm.cm. These specific devices can be peripheral devices, such as off chip coils or decoupling capacitors, without which the top and bottom chips would not be able to function properly. Advantageously, if only passive devices are needed to form the peripheral devices, masks are simple and an intermediate chip is thus very cheap.

As top and bottom chips are connected by flip chip bonding, this assembly allows avoiding the use of wires that introduce parasitic elements and limit performance, particularly the high frequency performance. Particularly, the invention allows short and efficient connections with peripheral devices integrated on said intermediate chip and dedicated to make the functioning of the top and bottom chips possible.

This assembly can be easily packaged by connecting said intermediate chip by flip chip bonding in order that said intermediate chip is linked to an external connection device allowing the connection with external circuits. Therefore, communications with external circuits are easy to implement and of good quality. Advantageously, said connection device is a lead frame type of package or a substrate that is then packaged. In the case where several intermediate chips are present in the assembly, only one intermediate chip is linked to the connection device by flip chip bonding.

This invention can be used with chips on which any kinds of devices are formed. However, interference between the different integrated devices that are very close together may occur rendering the functioning of the whole system constituted by the assembly not optimum. For example, devices operating at high frequency are very sensitive to parasitic elements. Besides, high power devices can generate damages in a very compact assembly such as the one of the invention.

In an advantageous embodiment, devices integrated on said bottom, intermediate and top chips are chosen in order that said devices are stacked in a specific order relative to said connection device making high performance possible for said assembly. This specific order is such that high-performance sensitive devices are integrated on the bottom chip while low-performance sensitive devices are integrated on the top chip.

This allows short connections for performance-sensitive devices and optimization of the linking of the different devices of the assembly. Effectively, high-frequency signal path and high-power signal path require very low-ohmic, low-inductive or low-impedance routing in order to preserve the high-frequency behavior and to maximize the energy yield of the power devices, respectively. The implementation of high-frequency or high-power devices is thus advantageously realized on the chip that is closest to the connection device and consequently on bottom chips.

In a preferred embodiment, said connection device includes a heatsink dedicated to be in contact with said bottom chip.

This allows having heat dissipative devices in contact with said heatsink. In such a case, heat dissipative devices are integrated on said bottom chip. Effectively, as the resulting assembly is very compact, strong heat dissipation can be generated within an assembly of the invention. Heat dissipation may be the result of high frequency or high-power devices integrated on the bottom chip.

In a specific embodiment, at least a heat dissipative device is integrated on said bottom chip, said bottom chip being in contact with said heat-sink.

In a specific embodiment, at least a high frequency device is integrated on said bottom chip, said bottom chip being in contact with said heat-sink.

The preferred embodiment allows separating devices such as temperature sensitive ones from heat-dissipative devices and making closer devices that are dedicated to work at high frequencies.

In a specific implementation, devices are integrated on both sides of said intermediate chip. Such a characteristic makes it possible to have more devices integrated on said intermediate chip. For example, devices dedicated to the top chip are integrated on the top side and devices dedicated to the functioning of the bottom chip are integrated on the bottom side. Via holes are used to realize connections between the two types of devices and for the direct connection of the top and the bottom chips.

The invention also relates to a packaged system including at least three devices that are integrated on separated chips that are arranged in an assembly according to the invention. An example of such a system is given in the following.

The invention finally relates to a method of manufacturing a miniaturized packaged system including at least a microelectronic assembly. It comprises a step of realizing at least one chip, called intermediate chip, including integrated devices on at least one face and via holes running through said chip and filled with conductive material, from a high-ohmic substrate. Then, according to the method of the invention a step is realized of linking at least one chip, called bottom chip and including integrated devices on one face, by flip chip bonding on said intermediate chip, in order that said via holes are in connection with terminal pads of said bottom chip. The intermediate chip is then linked by flip chip bonding on a connection device in order that said bottom chip is stacked between said intermediate chip and said connection device. Then a step is realized of linking by flip chip bonding a third chip, called top chip and including integrated devices on one face, on said intermediate chip, in order that said via holes are in connection with terminal pads of said top chip. At last the assembly is molded in a molding component.

Such a method allows a very compact system presenting the same functionalities than a larger one if realized by other techniques like integration on a single chip. Therefore, such a method avoids an integration of devices of different kinds on a same chip. The different chips are effectively realized independently and then assembled according to the invention.

### BRIEF DESCRIPTION OF THE DRAWINGS

The invention is described hereafter in detail with reference to the diagrammatic figures wherein:

FIG. 1 represents a microelectronic chip assembly according to the invention;

FIG. 2 illustrates an example of application for a system of the invention;

FIG. 3 represents a microelectronic chip assembly according to an embodiment of the invention;

FIG. 4 illustrates the steps of a method to manufacture a miniaturized packaged system according to the invention.

### DESCRIPTION OF EMBODIMENTS

The terms ‘top’ and ‘bottom’ are used herein to indicate directions relative to the structure of the microelectronic chip assembly itself or to a connection device. It should be understood that these terms are used to refer to the frame of reference of the assembly itself or to said connection device, and not to the ordinary, gravitational frame of reference.

The term ‘device’ designates any component, function, circuit, application that can be integrated on a microelectronic chip.

The term ‘system’ designates any combination of electronic functions to perform a complete application, excluding a single integrated circuit (IC).

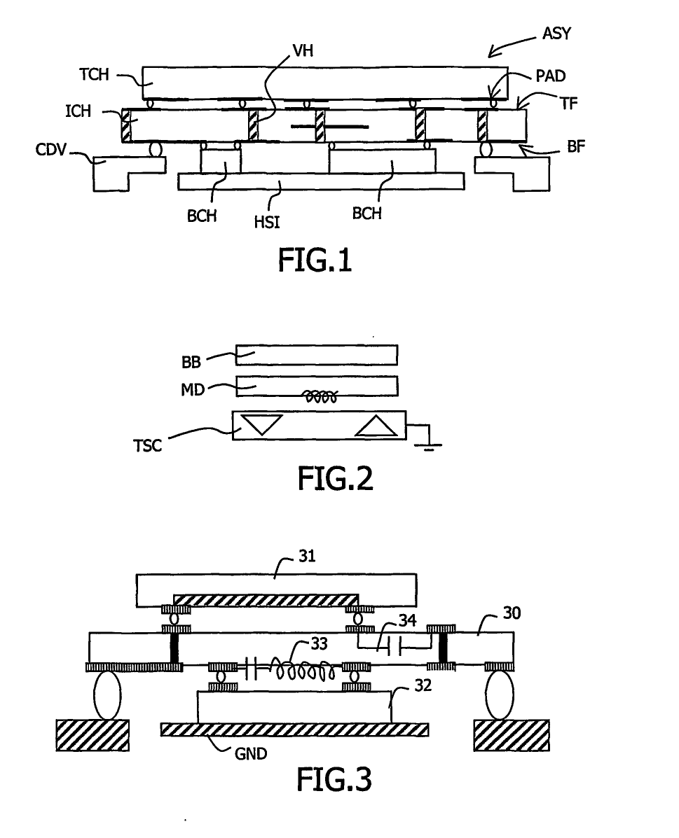

FIG. 1 represents a microelectronic chip assembly ASY according to the invention. This assembly includes three microelectronic chips TCH, ICH, BCH on which integrated devices are formed. Integrated devices are integrated using semi-conductor or semi-insulating technologies.

Bolder lines on this Figure symbolize terminal pads PAD. These terminal pads are made of conductive material coated on the chip. Said terminal pads are part of the integrated devices formed on chips.

The three chips are stacked together. One of the chips, called intermediate chip ICH, is realized from a high-ohmic substrate and includes via holes VH running through said intermediate chip ICH and filled with conductive material. Said via holes are linked to terminal pads integrated on at least one surface of said intermediate chip ICH. Said intermediate chip ICH can thus also include terminal pads on both sides: bottom face BF and top face TF.

The two other microelectronic chips, called top and bottom chips TCH and BCH, are connected by flip chip bonding on top face TF and bottom face BF of said intermediate chip ICH. Said top and bottom chips TCH and BCH are thus linked to said intermediate chip ICH by an electrical connection as known in the flip chip bonding field.

The flip chip bonding interconnection method offers a short signal path and consequently a more rapid communication between devices than can other methods, such as tape automated bonding or conventional wire bonding. Moreover, bonded terminal pads are not restricted to the periphery of the chip. Terminal pads are located at points of interconnection. For example, bumps are formed by plating of several layers of metals on the terminal pads of the chip dedicated to be connected by flip chip bonding. Following deposition, the chip is heated to reflow the metals, thus causing surface tension of the deposit to form hemispherical solder bumps. Therefore top and bottom chips are subsequently severed from the wafer which they were part of and flipped for alignment with the terminal pads and/or the via holes VH on said intermediate chip ICH. These bumps are thus contacted with the terminal pads and/or via holes VH of said intermediate chip ICH and uniformly heated to simultaneously form interconnection between terminal pads of the intermediate chip aligned with the ones of top and bottom chips. A method describing the different steps using such flip chip bonding is presented hereinafter. Any other technique to realize a flip chip bonding between two chips can also be used. For example, an adhesive layer including micro balls of conductive material to realize electrical connections can also be used in order to realize the bonding and the connection without any bumps. Such techniques and others are well known within microelectronic field.

The main advantage of flip chip bonding is that connections are direct and avoid the use of wires. According to the invention, said via holes VH are directly connected to pads of said top and bottom chips in order to realize electrical connections directly between top and bottom chips or between intermediate chip and top or bottom chip.

The assembly constituted by the three chips is then disposed on a connection device CDV that can be a substrate or a lead frame. Connection between said substrate or lead frame and the assembly is realized by linking said intermediate chip ICH by flip chip bonding with said connection device CDV. This connection device CDV allows the connection with external circuits. Such a connection device CDV is well known by the man skilled in the art of packaging.

In a preferred embodiment, the connection device includes a heat sink that is intended to be in contact with the bottom chip BCH. This allows the evacuation of energy that could accumulate in the assembly of the invention. As the invention makes it possible to have a very compact system, this feature is important as energy could accumulate and deteriorate the system.

According to the invention, the different devices integrated on different chips are interconnected by the use of the intermediate chip, which contains the necessary peripheral devices to make the different devices integrated on top and bottom chips working.

FIG. 2 represents an example of application for a system of the invention. It consists in an electronic function for which the necessary devices can be split across three chips. In such a case the invention permits to optimize the performance and cost.

The invention is thus very advantageous when different kind of devices requiring different manufacturing requirements need to be present in a system. For example, a system is constituted by a power device and passive devices possibly connected with said power devices. Signal processing devices are also generally part of the system. All these different devices require different kinds of integration. The invention allows building a compact system comprising all these devices while keeping a very simple manufacturing process. Effectively, the different chips comprising the different kind of devices are formed separately before being connected to each other by the method of the invention.

FIG. 2 illustrates an embodiment of the invention comprising an integrated high-frequency transceiver TSC and a digital base-band solution BB. Said high-frequency transceiver TSC requires passive devices MD comprising at least inductors and decoupling capacitors as well as high-frequency matching devices. The invention allows dividing these different devices among three different chips. Said high-power and high-frequency devices are advantageously integrated on the bottom chip in order to be close to the heat-sink in the preferred embodiment of the invention. Therefore, the passive devices MD can be integrated on the intermediate chip ICH in order to have short connections to high-power and high-frequency devices formed on the bottom chip. This implementation also provides good connection to ground for high-frequency devices through said intermediate chip ICH connected to said connection device. Effectively, the RF front-end section of the transceiver requires high quality ground connection. The invention has an economical advantage as matching devices like inductors are built on the intermediate chip realized on cheap high-ohmic substrate.

In a system according to the invention, there is no need that the complete substrate is high-ohmic; certain zones can be high-ohmic whereas others may be low-ohmic. Preferably the inductor of the RF section requires the low-ohmic zones.

Besides, the integration of passive devices requires the use of fewer masks than, for example, the integration of digital devices. It renders the resulting intermediate chip cheap. The digital base-band and programmable circuitry is realized on the top chip TCH. Such devices work correctly even under low quality ground connection. Moreover, they are generally not heat dissipative.

A specific order from the bottom to the top chip is presented here. In this example, the intermediate chip is integrated on a single face wherein the passive elements for the high frequency and power devices formed on the bottom chip are formed. Contacts with the top chip are provided by said via holes formed through the intermediate chip. The invention includes also the case where devices are formed on both sides of said intermediate chip. In this case, devices that are dedicated to interact with devices formed on the top chip are integrated on the other (top) side of the intermediate chip.

One full package system according to the invention includes digital low-power devices, high-power devices, memories, analog devices, high-frequency small signal devices, high-power analog devices, high-frequency devices. This list is not exhaustive. By generalization of the invention to any kinds of devices present in the system, the specific order of the advantageous embodiment is, from the bottom to the top, from performance-sensitive devices such as high-frequency devices to low performance-sensitive devices such as digital devices having low power consumption.

According to this specific order, power devices including digital devices with high power consumption are formed on a bottom chip directly in contact with the heat-sink High frequency devices including radio-frequency devices are also directly in contact with the heat-sink. High-performance analog devices are also formed on a bottom chip. This allows good power dissipation and low impedance ground connection necessary for high-frequency devices. The different kinds of devices can be integrated on one single bottom chip or on several bottom chips. Thus any performance-sensitive devices are advantageously implemented on said bottom chips.

According to this specific order, applications of the devices formed on the bottom chip are advantageously integrated on the bottom face BF of said intermediate chip ICH. Such applications include matching devices in the example presented above. If ever said applications are integrated on the top face TF, interconnection with devices integrated on said bottom chip are realized by via holes through the intermediate chip. However, connections of said bottom chip are of less good quality than if said applications were implemented on the bottom face, since these connections are longer taking the via holes into account

According to the specific order, the top chip or several top chips include low-power devices, low-frequency analog devices, low-power digital devices and memories. This list is not exhaustive. Any low-performance sensitive devices are advantageously integrated on said top chips, which are linked to said intermediate chip by flip chip bonding. Connections with devices integrated on intermediate and bottom chips are provided by via holes.

The top face TF of the intermediate chip advantageously comprises the necessary devices to make devices integrated on the top chip work properly. It can also be noted that ground connections are still of good quality as top chips are directly connected to the intermediate chip that is connected to ground through the connection device.

Therefore, the invention proposes an optimized multi-application assembly to achieve an optimized system performance in a miniaturized and cheap system-in-a package construction. By extension, several sandwiches of chips can be stacked in order to cope with multiple applications. In such an extension, several intermediate chips are needed. Notwithstanding the order, from the bottom to the top, high frequency applications, devices requiring low impedance connections to low-power, low-frequency applications need to be prevented from high power consumption. For example, the preferred order is from high-power to low-power devices and from high-frequency to low-frequency devices from the bottom to the top. A general characterization of the preferred order is from high performance-sensitive devices to low performance-sensitive devices.

The absence of bonding wires, which are known to limit the high-frequency performance of the electronic systems and which generate interferences thus degrading signal integrity makes it possible to achieve good performance.

FIG. 3 diagrammatically illustrates a microelectronic chip assembly according to an embodiment of the invention. In this embodiment, examples of peripheral devices to be used by the top and bottom chips 31, 32 and arranged on the opposite faces of the intermediate chip 30 are shown. Here the bottom chip is close to the connections to external circuits. Therefore, high-performance chips are preferably integrated on the bottom chip 32. The bottom chip 32 can be for example a high-frequency high-power die glued on the ground GND and connected to the intermediate chip by flip chip bonding, represented by balls stocked between circuit pads. The bottom chip uses a coil 33 arranged on the bottom face of the intermediate chip 30. The top chip 31, which can be for example a digital IC connected to the intermediate chip by flip chip bonding, uses a voltage supply decoupling capacitor 34 arranged on the top face of the intermediate chip 30. Vertical hatches represent circuit pads. Biased hatches represent digital circuits with active devices. Via holes are represented by vertical bold lines running through the intermediate chip 30.

An array of peripheral components in/on the intermediate chips can also be used, which makes the whole assembly smaller and also cheaper. Examples of such peripheral components are resistors, capacitors of different size (vertical trench caps, thin film Metal-insulator-metal caps, inductors, etc.).

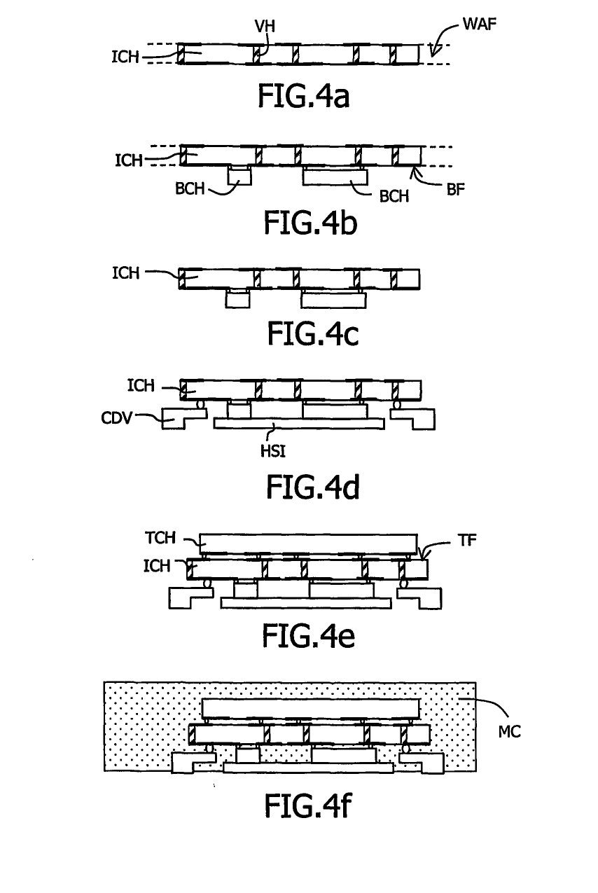

FIG. 4a to 4f describe the main steps of a method of the invention to manufacture a miniaturized packaged system including at least a microelectronic assembly according to the invention.

FIG. 4a represents a wafer WAF on which are formed the intermediate chips ICH. On the FIG. 4a is only represented one intermediate chip ICH. Others are integrated beside it on said wafer represented by a dotted line. Said intermediate chip includes integrated devices on at least one face and via holes VH running through said chip and filled with conductive material. Said via holes VH are realized according to a well-known microelectronic technique.

Bottom chips are realized separately. They include integrated devices on one face. Then at least one bottom chip is linked by flip chip bonding to said first wafer in order that terminal pads of said bottom chip are aligned with terminal pads, notably the ones in connection with said via holes of said intermediate chip. This is represented on FIG. 4b. Bottom chips are linked to the bottom face BF of said intermediate chip ICH. The ‘bottom’ representation in FIG. 4 is relative to the final assembly and not to the different position that can be taken up by the intermediate chip and other chips during execution of the method.

Then said wafer on which said bottom chips are flipped is cut. A microelectronic intermediate assembly as represented in FIG. 4c is thus obtained.

Said intermediate chip with flipped bottom chip is then linked by flip chip bonding to a connection device CDV. Said bottom chip is thus stacked between said intermediate chip and said connection device CDV. Advantageously, said bottom chips are put in contact with a heat-sink as presented above. Said heat-sink is part of said connection device. Thus said bottom chip is stacked between said intermediate chip and said heat-sink as represented on FIG. 4d.

A third chip called top chip is then linked by flip chip bonding to the top face TF of said intermediate chip by aligning said via holes with pads on said top chip. FIG. 4e represents the resulting assembly.

Finally, according to packaging technology, the assembly is molded in a molding component MC. A packaged system as represented on FIG. 4f is thus obtained.

Presented figures are illustrative of special embodiments of the invention and are not restrictive. It will be apparent to those skilled in the art that many modifications and variations may be made to the exemplar embodiments of the present invention list forth above, without departing substantially from the principles of the present invention. All such modifications and variations are intended to be included herein.

1. A microelectronic chip assembly comprising
at least three microelectronic chips that are stacked together, at least one of the chips, denoted intermediate chip, comprising via holes filled with conductive material running through said chip, characterized in that
said intermediate chip is realized from a high-ohmic substrate comprising
devices to be used by at least two other microelectronic chips, called top and bottom chips, are arranged on at least one face of said intermediate chip, said top and bottom chips being connected by flip chip bonding on top and bottom faces of said intermediate chip, respectively, said via holes realizing an electrical connection between pads of said top and bottom chips.

2. An assembly as claimed in claim 1, wherein said intermediate chip, which is also linked by flip chip bonding to an external connection device, makes the connection with external circuits possible.

3. An assembly as claimed in claim 2, wherein high and low-performance sensitive devices are integrated on said bottom, intermediate and top chips in order that said devices are stacked in a specific order relative to said connection device, said specific order being such that high-performance sensitive devices are integrated on the bottom chip and low-performance sensitive devices are integrated on the top chip.

4. An assembly as claimed in claim 2, wherein said connection device includes a heatsink dedicated to realize a contact with said bottom chip.

5. An assembly as claimed in claim 4, wherein at least a heat dissipative device is integrated on said bottom chip, said bottom chip realizing a contact with said heat-sink.

6. An assembly as claimed in claim 4, wherein at least a high-frequency device is integrated on said bottom chip, said bottom chip being in contact with said heatsink.

7. An assembly as claimed in claim 1, wherein said intermediate chip comprises integrated devices on both sides.

8. A packaged system including at least three devices that are integrated on separate chips, characterized in that said chips are arranged in an assembly as claimed in claim 1.

9. A method of manufacturing a miniaturized packaged system including at least a microelectronic assembly, characterized in that said method includes the steps of:
realizing at least one chip from a high-ohmic substrate, called intermediate chip, including integrated devices on at least one face and via holes running through said chip and filled with conductive material,
linking at least one chip, called bottom chip, including integrated devices on one face, by flip chip bonding on said intermediate chip, in order that said via holes are connected with terminal pads of said bottom chip,
linking the intermediate chip by flip chip bonding on a connection device in order that said bottom chip is stacked between said intermediate chip and said connection device,
linking by flip chip bonding a third chip, called top chip, including integrated devices on one face, on said intermediate chip, in order that said via holes are in connection with terminal pads of said top chip,
molding the assembly in a molding component.
